(19) United States
(12) Patent Application Publication
(10) Pub. No.: US 2012/0266942 A1
(43) Pub. Date: Oct. 25, 2012

(54) SEAL SHEET AND SOLAR CELL MODULE

(75) Inventors: Masaaki KOMATSU, Hitachi (JP); Choichiro Okazaki, Mito (JP); Hiroki Yamamoto, Hitachi (JP)

(73) Assignee: Hitachi Chemical Company, Ltd.

(21) Appl. No.: 13/455,158

(22) Filed: Apr. 25, 2012

(30) Foreign Application Priority Data
Apr. 25, 2011 (JP) 2011-097196

(51) Int. Cl. H01L 31/055; C09K 11/02

(52) U.S. Cl. 136/247; 252/301.36

(57) ABSTRACT

To improve the efficiency of a wavelength conversion film, and improve the photoelectric conversion efficiency of a solar cell. In a solar cell module having a front glass, a sealing material, a solar battery cell and a back sheet, a wavelength conversion material is mixed into the sealing material. In the wavelength conversion material, a fluorescent substance whose surface is coated with polymer which emits green to near infrared light when excited by near ultraviolet to blue light is sealed. This reduces the quantity of light in sunlight which is not oriented toward the solar battery cell, thereby achieving high efficiency of wavelength conversion as well as improvement of the photoelectric conversion efficiency of the solar cell.

### CLAIM OF PRIORITY

The present application claims priority from Japanese Patent Application JP 2011-097196 filed on Apr. 25, 2011, the content of which is hereby incorporated by reference into this application.

### TECHNICAL FIELD

The present invention relates to a technique of a wavelength conversion film, and in particular to a technique which is effective when applied to a solar cell and involves irradiating a fluorescent substance with near ultraviolet to blue light to excite the fluorescent substance, causing light emission to convert the wavelength of the light.

### BACKGROUND OF THE INVENTION

The quantum efficiency of a solar cell is generally lower in the region from ultraviolet to blue than in the region from green to near infrared. Therefore, among the wavelength components of the light which reach the solar cell, light with high quantum efficiency for the solar cell can be increased to improve the efficiency of the solar cell by converting the wavelength of ultraviolet to blue light into that of green to near infrared light. It has been known that the efficiency of the solar cell is improved by placing a wavelength conversion film on the path of light to a solar cell. For example, in Japanese Unexamined Patent Publication No. 2001-7377, a fluorescence coloring agent is used as a wavelength conversion material. Moreover, in Japanese Unexamined Patent Publication No. 2000-327715, a rare earth metal complex-containing ORMOSIL complex is used. In 58^{th} Symposium of Japan Society of Coordination Chemistry, preliminary reports 1PF-011, an organic metal complex is used. However, durability is insufficient in the above-mentioned fluorescence coloring agent and organic metal complex, and it is difficult to maintain the functions as a wavelength conversion material for solar cells over a long period of time. In Japanese Unexamined Patent Publication No. 2003-218379, a wavelength conversion material for solar cells using a fluorescent substance is described while no specific value of improvement of the efficiency in Japanese Unexamined Patent Publication No. Hei 7-202243 is described, and improvement in the power generation efficiency is also insufficient in Japanese Unexamined Patent Publication No. 2005-147889. Japanese Unexamined Patent Publication No. 2005-147889 describes covering a light emission material with metal oxide to improve the light transmission coefficient, but as described in Japanese Unexamined Patent Publication No. 2005-147889, surface coating materials for fluorescent substances are generally metal oxide, and there is no description of coating its surface on inorganic compounds of fluorescent substance with polymer.

### SUMMARY OF THE INVENTION

Wavelength conversion materials for solar cells have been under improvement through the use of fluorescent substances which are organic metal complexes and inorganic compounds as wavelength conversion materials for solar cells. However, in known wavelength conversion materials, light scattering caused by the light emission material is great, and therefore the amounts of components of light which are not oriented toward the solar battery cell but are reflected to the side where sunlight is incident are great. Accordingly, in known wavelength conversion materials, the photoelectric conversion efficiency of the solar cell has not been sufficiently improved, and further improvement of the photoelectric conversion efficiency has been required.

The present invention has been made in view of the above object, and an object of the same is to provide a technique which is capable of increasing the amount of light oriented toward the solar battery cell of the light which is incident on a wavelength conversion material, and improving the photoelectric conversion efficiency of a solar cell.

The above and other objects and novel features of the present invention will be apparent from the description and accompanying drawings of the present specification.

Among the inventions disclosed in the present application, a typical example can be briefly explained as follows:

That is, a solar cell module in one embodiment of the present invention has a front glass, a clear resin, a solar battery cell and a back sheet. Moreover, the front glass is semitempered glass for solar cells, and may have an antireflection coating in some cases. In the clear resin, a fluorescent substance which emits visible to near infrared light by being excited by near ultraviolet to blue light is contained. The fluorescent substance is in the form of being coated with polymer on its surface so that reflected light is reduced to increase the amount of light oriented toward the solar battery cell. That is, by using the solar cell in the wavelength conversion film as stated above, a solar cell module having high photoelectric conversion efficiency can be produced.

The effects obtained by a typical example of the inventions disclosed in the present application can be briefly explained as follows:

That is, in the present invention, reflection caused by a wavelength conversion material can be reduced, the quantity of light oriented towards the solar battery cell can be increased, and the photoelectric conversion efficiency of the solar cell can be improved.

### BRIEF DESCRIPTION OF THE DRAWINGS

FIG. 1 is a schematic diagram of a solar cell module when a wavelength conversion material is mixed into a sealing material;

FIG. 2 is a schematic diagram of the solar cell module when a wavelength conversion layer is formed between the sealing material and a solar cell element;

FIG. 3 is a schematic diagram of a solar cell module when a wavelength conversion material is mixed into an antireflection coating;

FIG. 4 is a schematic diagram of the solar cell module when a wavelength conversion layer is formed between an antireflection coating and a solar cell element;

FIG. 5 is a schematic diagram of a concentrator solar photovoltaic system in which a solar cell module is incorporated into a concentrator solar cell;

FIG. 6 is a schematic diagram of a wavelength conversion material which is a fluorescent substance whose surface is coated with polymer;

FIG. 7 is a graph which shows the refractive index dependence of reflected light intensity on the polymer in the wavelength conversion material;

FIG. 8 is a graph which shows the dependence of an increase in the generated output of the solar cell on excitation edge wavelength of the wavelength conversion material; and

FIG. 9 is a graph which shows the dependence of the light scattering intensity on particle diameter.

### DESCRIPTION OF THE PREFERRED EMBODIMENTS

### <Structure of Solar Cell Module>

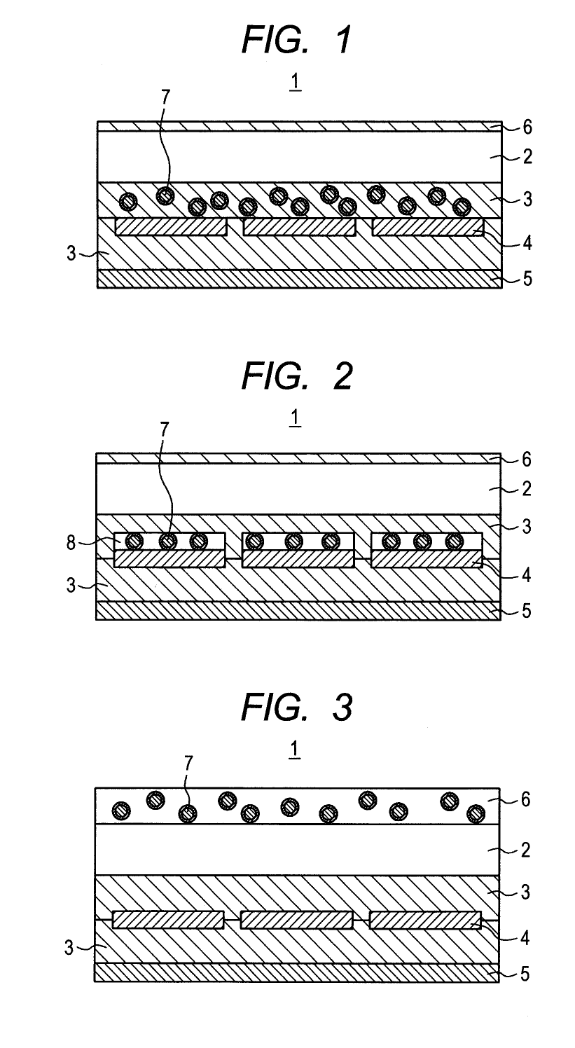

The structure of the solar cell module of the present invention is shown in FIG. 1. A solar cell module 1 includes a front glass 2 which is placed on the side where sunlight is incident, a sealing material (clear resin) 3, a solar battery cell (solar cell element) 4, and a back sheet 5, and an antireflection coating 6 is formed on the side where sunlight is incident of the front glass 2. It is desirable that the antireflection coating is present, but it may not be necessarily present. As components for the front glass 2, in addition to glass, materials can also be used as long as they are clear so that they do not prevent incidence of sunlight, such as polycarbonate, acryl, polyester, and polyethylene fluoride.

Moreover, the sealing material 3 plays a role of a protective material, and is disposed in a manner of covering a solar battery cell 4 which converts light energy into electric energy. A potting material of silicon, polyvinyl butyral and the like can be used as the sealing material, in addition to EVA (ethylene-vinyl acetate copolymer). As the solar battery cell 4, a single crystal silicon solar cell, a polycrystal silicon solar cell, a thin-film compound semiconductor solar cell, an amorphous silicon solar cell and various other solar cell elements can be used. A single or multiple solar battery cells 4 are disposed in the solar cell module 1, and when multiple solar battery cells 4 are disposed, they are electrically connected by interconnectors.

Moreover, the back sheet 5 may include a metal layer and a plastic film layer to provide weathering resistance, high insulating properties, and strength. The wavelength conversion material 7 can be used by being mixed into the sealing material 3 as shown in FIG. 1. In this case, the sealing material 3 absorbs near ultraviolet to blue light and constitutes a wavelength conversion layer which emits green to near infrared light. Moreover, since the wavelength conversion film is produced along with the sealing material 3 in the solar cell module, the manufacturing process can be simplified.

Moreover, the wavelength conversion material 7 may take any form as long as it is present while at least sunlight is incident on the solar battery cell 4, and it is present on a light receiving surface of at least the front glass 2 or between the front glass 2 and solar battery cell 4. Moreover, the wavelength conversion material 7 may take any form as long as it can absorb the light which is incident on the solar battery cell. Therefore, it may be in any position as long as the position allows the converted light to be provided to an incident portion of sunlight of at least the solar battery cell 4, and may not be uniformly present with the same area as the surface area of the solar cell module 1.

Therefore, as the structure of the solar cell module in addition to the constitution shown in FIG. 1, the wavelength conversion layer 8 can be formed on the solar battery cell side of the sealing material 3 as shown in FIG. 2. The wavelength conversion film 8 is a film containing the wavelength conversion material 7. In this case, the distance from the wavelength conversion material 7 to the solar cell element of light emitted is short, so that diffusion of light can be suppressed.

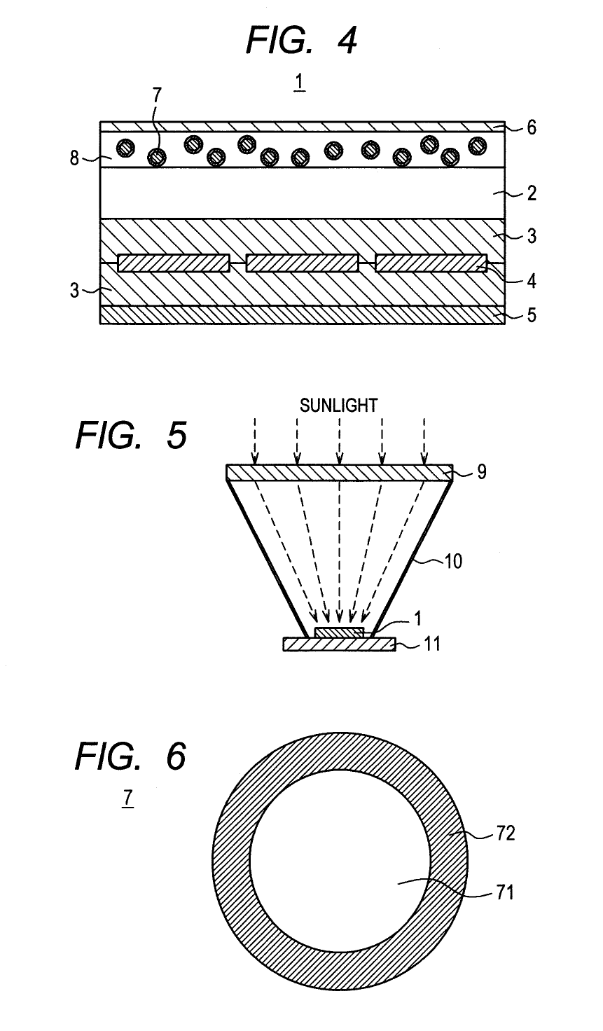

Moreover, as shown in FIG. 3, when the antireflection coating 6 is provided, the wavelength conversion material 7 can be used by being kneaded into the antireflection coating 6. In this case, the manufacturing process can be simplified since the wavelength conversion film is produced with antireflection coating 6. Moreover, in order to form a wavelength conversion film on the surface of the front glass where there is no absorption of ultraviolet light by the front glass 2, the wavelength of ultraviolet light can be converted into that of visible to near infrared light.

Moreover, as shown in FIG. 4, the wavelength conversion film 8 can be formed between the antireflection coating 6 and the front glass 2. In this case, in order to form the wavelength conversion film 8 on the surface where there is no absorption of ultraviolet light by the front glass 2, the wavelength of ultraviolet light can be converted into that of visible to near infrared light. Moreover, a condensing lens 9, a supporting frame 10, a substrate 11 and other components may be additionally provided in the above-described constitution to form a concentrator solar cell as in FIG. 5. Since light with a short wavelength in high energy is converted into light with a long wavelength and low energy by the wavelength conversion material, excessive energy higher than the band gap of the solar cell element is decreased, and a rise in temperature of the solar cell element can be suppressed even if it is used as a concentrator solar cell.

As mentioned above, methods for producing a solar cell having a structure in which a material containing the fluorescent substance is placed on the path of light to the solar cell include a method of mixing in materials of the front glass 2 and sealing material 3, a method of adding the wavelength conversion material 7 in an appropriate solvent and applying the resulting mixture to a desired portion, among others. The method may be in any form as long as it does not prevent absorption of sunlight in the solar battery cell 4 or impair the functions of the wavelength conversion material 7. Among them, the method of using the wavelength conversion material 7 by kneading the same into the sealing material 3 shown in FIG. 1 is excellent as a method of placing the wavelength conversion material 7 since it can simplify the production method.

### <Polymer Surface-Coated Light Emission Material>

In the case where a fluorescent substance material is used as the wavelength conversion material, when the size of the fluorescent substance is the order of a few μm, a component of light which is not oriented toward the solar battery cell by the reflection caused by the fluorescent substance but is reflected to the side where sunlight is incident occurs. In this case, the component reflects to the side where the component of sunlight is incident by the fluorescent substance material placed as the wavelength conversion material and does not contribute to the power generation of the solar cell.

By coating the surface of the fluorescent substance with polymer, the reflection of sunlight by the fluorescent substance can be suppressed. Metal oxides are generally known as materials for coating the surface of the fluorescent substances. They are often used in surface coating as fine particles, and materials which smoothly coat the surface of the fluorescent substance are preferable to increase light use efficiency. Moreover, the surface coating is preferable in that it can be produced easily and economically.

FIG. 6 shows a schematic diagram of a wavelength conversion material which is a fluorescent substance whose surface is coated with polymer. That is, by coating the surface of a fluorescent substance 71 which is a light emission material, with a polymer 72 having an index of refraction greater than that (1.5) of the sealing material but smaller than that of the fluorescent substance 71 (although depending on the composition of fluorescent substance, the range of the index of refraction of the fluorescent substance is from about 1.5 to 2.0), the reflection of sunlight can be reduced. Herein, when the index of refraction of the sealing material 3 is a, the index of refraction of the fluorescent substance 71 is b, and the index of refraction of the polymer 72 to be surface-coated is c, a<c<b is held.

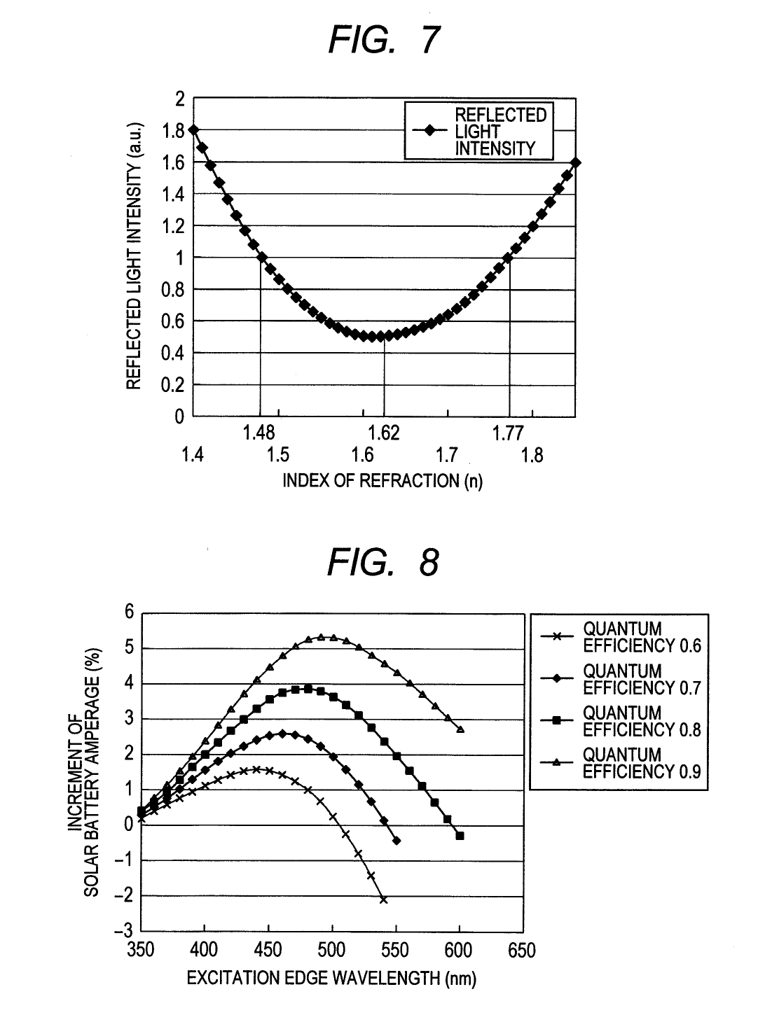

FIG. 7 shows the results of calculation of the reflected light intensity when the index of refraction of the polymer 72 coated on the surface of the fluorescent substance is varied. When EVA is used as the sealing material 3, the index of refraction of EVA is 1.48. Moreover, when BaMgAl₁₀0₁₇:Eu, Mn is used as a fluorescent substance material, the index of refraction of BaMgAl₁₀0₁₇:Eu, Mn is 1.77. The reflected light intensity is decreased in the range that the index of refraction of the polymer 72 to be surface-coated is higher than 1.48 and lower than 1.77, and the reflected light intensity is reduced by 50% at 1.62. Moreover, since the effects in reducing the reflected light intensity can be sufficiently expected when the reflected light intensity is reduced by 20%, the index of refraction of the polymer 72 is preferably in the range higher than 1.51 and lower than 1.73. Moreover, the thickness of the polymer 72 coated on the surface of the fluorescent substance 71, is preferably thicker than λ/4 of ultraviolet light, considering the prevention of reflection of ultraviolet light in components of sunlight. Therefore, the thickness of the polymer 72 is preferably 70 nm or more. Herein, the polymer 72 generally indicates polymer formed by high molecules having a molecular weight of ten thousand or higher, but herein the polymer 72 may be formed in a desired thickness, and is not limited to polymer having a molecular weight of ten thousand or higher. Moreover, the composition of the materials of the polymer 72 contains resins, plastics, high molecules, polymers and the like, which include acrylic resins, polyethylene and vinyl chloride resins. These can be used as long as they do not prevent utilization of light. Among these, acrylic resins (methyl methacrylate resins) have the index of refraction in the ultraviolet light region slightly higher than the literature data (1.49), and are therefore suitable as surface coating materials. Moreover, the wavelength conversion film 8 containing the light emission material whose surface is coated with the polymer 72 mixed thereinto may be a single layer, or may be stacked to have a multilayer structure.

### <Excitation Edge Wavelength, Particle Diameter, and Concentration of Addition as Wavelength Conversion Material>

The quantum efficiency of the solar cell generally lowers from blue to near ultraviolet, as the wavelength of incident light becomes shorter. In contrast, the fluorescent substance having a quantum efficiency of about 0.7 to 0.9 is used as the wavelength conversion material. FIG. 8 shows the results of provisional calculation of an increase in the generated output when the excitation edge wavelength on the long-wavelength side of the fluorescent substance having an excitation band at 300 nm or higher, where there is the spectrum intensity of sunlight, is varied. Herein, the excitation edge wavelength means a wavelength at which the excitation strength on the long-wavelength side rises in the excitation spectrum, and indicates the wavelength which is equivalent to 10% of the peak intensity of the excitation spectrum.

An increase in the generated output due to wavelength conversion is found at the excitation edge wavelength of 350 to 670 nm with quantum efficiency of 0.6 to 0.9. The increase in the generated output is greatest when the excitation edge wavelength is 430 to 500 nm. That is, if the quantum efficiency of the wavelength conversion material is 0.6 to 0.9, the generated output of the solar cell can be maximized by using a wavelength conversion material with an excitation edge wavelength ranging from 430 to 500 nm, while if the quantum efficiency is 0.7 to 0.9, the generated output of the solar cell can be maximized by using a wavelength conversion material with an excitation edge wavelength ranging from 450 to 500 nm. Moreover, when the quantum efficiency of wavelength conversion material is 0.7 or higher, even if a wavelength conversion material having an excitation edge wavelength of 410 to 600 nm is used, the generated output of the solar cell can be improved than in the case of wavelength conversion using a known organic complex (quantum efficiency: about 0.6).

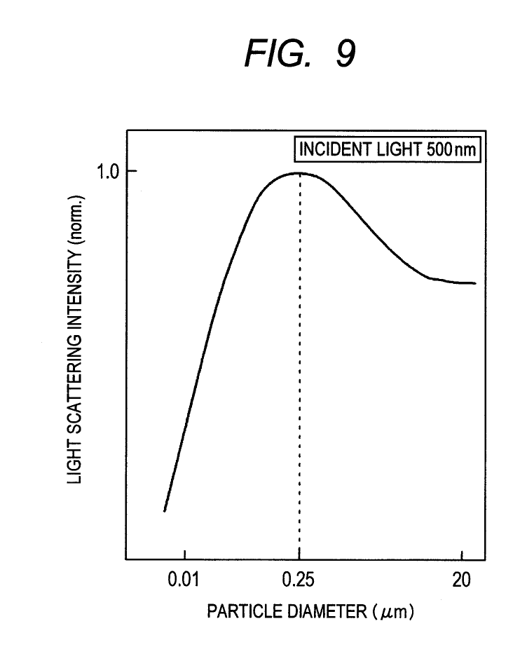

In contrast, the fluorescent substance also has a loss due to optical scattering, and its degree relates to its particle diameter and concentration of addition. The relationship between the particle diameter and light scattering intensity of the wavelength conversion material is such that, when the wavelength of sunlight is 500 nm, the light scattering intensity is the highest with a particle diameter of 250 nm, which is half the wavelength, due to the Mie scattering. The relationship between the light scattering intensity and particle diameter is shown in FIG. 9.

The scattering intensity is controlled by the Rayleigh scattering with a particle diameter smaller than 250 nm, and the smaller the particle diameter, the lower the scattering intensity, while it is controlled by geometrical optics scattering with a particle diameter larger than 250 nm, and the larger the particle diameter, the lower the light scattering intensity. The light scattering intensity is lowered when the particle diameter is small, but the emission intensity of the fluorescent substance is lowered. Also the concentration of addition needs to be increased when the particle diameter is too large, which impairs functions of the sealing material. Therefore a particle diameter ranging from 10 nm to 50 μm is appropriate. In addition, the light emission efficiency of the fluorescent substance tends to abruptly lower at 1 μm or lower, and therefore more preferably, the particle diameter ranging from 1 μm to 50 μm is appropriate.

Next, the concentration of addition of the wavelength conversion material to the sealing material is desirably such that at least one fluorescent substance particle is present on the side where sunlight is incident and the fluorescent substance mixed into the sealing material is evenly exposed to sunlight. When the concentration of addition is too high, the optical scattering is increased, while when the concentration of addition is too low, an amount of light which passes through the material with its wavelength not converted increases. Accordingly, the concentration of addition of the fluorescent substance having an average particle diameter of 2.3 μm is 2% by weight. Moreover, the concentration of addition of the fluorescent substance having an average particle diameter of 5.8 μm is 5% by weight. Further, the concentration of addition of the fluorescent substance having an average particle diameter of 1.2 μm is 1% by weight. Therefore, the concentration of addition of the fluorescent substance having an average particle diameter of 1 to 5 μm is 1 to 5% by weight. However, this is the required amount of the fluorescent substance obtained by calculation herein, and the optimum concentration lies around this amount. Therefore, when an average particle diameter of the fluorescent substance is A (μm), an optimum concentration range B (% by weight) starts to exhibit its effects from about 1/200 times the optimum concentration 2 A/2.3, and the effects are found up to about 10 times. Therefore, the concentration of the fluorescent substance is good in the range from 0.004 A≦B≦8.7 A. Considering stopping and light scattering of light, more preferably, the effects of wavelength conversion is high in the range from about 1/100 times to about five times the optimum concentration 2 A/2.3. Therefore, it is thought that the concentration of the fluorescent substance is optimal in the range from 0.008 A≦B≦4.3 A. Moreover, the concentration of addition of the fluorescent substance can only be lowered when reflected light is great, but the reflected light can be reduced by coating its surface with polymer. Therefore, the concentration of addition of the wavelength conversion material can be higher than in conventional cases.

### <Composition of Fluorescent Substance Used For Wavelength Conversion Material>

A preferable wavelength conversion material is capable of converting near ultraviolet to blue light at 500 nm or lower into green to near infrared light at 500 nm to 1100 nm and causing the light to be incident on the solar battery cell. In particular, a material is preferable which has an excitation band at 300 nm or higher where there is the sunlight spectrum intensity, a quantum efficiency of 0.7 or higher, and has an excitation edge wavelength at 410 to 600 nm. Especially, a material having an excitation edge wavelength at 430 to 500 nm is the most preferable. In addition, in terms of luminance lifetime and moisture resistance, inorganic fluorescent substance materials used for various kinds of displays, lamps, and white LEDs and other devices are preferable. However, they are limited to those which have their excitation bands distributed in near ultraviolet to blue light. In the present invention, the composition of the fluorescent substance material in which the excitation band exists in near ultraviolet light to blue light from such a perspective, and which has a high phototransformation efficiency is selected.

Such fluorescent substances include, among others, MMgAl₁₀O₁₇:Eu, Mn, wherein M is a fluorescent substance which is one or more elements selected from Ba, Sr and Ca, or a fluorescent substance whose parent material contains one of (Ba, Sr)₂SiO₄, (Ba, Sr, Ca)₂SiO₄, Ba₂SiO₄, Sr₃SiO₅, (Sr, Ca, Ba)₃SiO₅, (Ba, Sr, Ca)₃MgSi₂O₈, Ca₃Si₂O₇, Ca₂ZnSi₂O₇, Ba₃Sc₂Si₃O₁₂ and Ca₃Sc₂Si₃0₁₂, or a fluorescent substance whose parent material is represented by MAlSiN₃, wherein M is one or more elements selected from Ba, Sr, Ca and Mg.

Moreover, an average particle diameter of the fluorescent substance used in the present invention is 10 nm to 50 μm, and is more preferably 1 μm to 50 μm, considering the light emission efficiency. Herein, an average particle diameter of the fluorescent substance can be defined as follows: methods for determining an average particle diameter of particles (fluorescent substance particles) include, among others, a method of determining by a particle size distribution measuring device and a method of directly observing by an electronic microscope. For example, in the case of using an electronic microscope, an average particle diameter can be calculated as follows: the sections of the variables of the particle diameter of particles ( . . . , 0.8 to 1.2 μm, 1.3 to 1.7 μm, 1.8 to 2.2 μm, . . . , 6.8 to 7.2 μm, 7.3 to 7.7 μm, 7.8 to 8.2 μm, . . . ) are represented by class values ( . . . , 1.0 μm, 1.5 μm, 2.0 μm, 7.0 μm, 7.5 μm, 8.0 μm, . . . ), which are represented by xᵢ. When the frequency of the variables observed by using the electronic microscope is indicated by fᵢ, an average value A can be represented as follows:

A=Σ×ᵢfᵢ/Σfᵢ−Σ×ᵢfᵢ/N

However, Σfᵢ=N. The excitation band wavelength of the fluorescent substance of the present invention falls within the satisfactory range as the wavelength conversion material, and therefore can provide excellent effects as a wavelength conversion material for solar cells.

### <Production of Wavelength Conversion Material>

A wavelength conversion material, which is a fluorescent substance whose surface is coated with polymer, is produced according to a first embodiment. Methyl methacrylate monomer is used as a raw material of the polymer. BaMgAl₁₀O₁₇:Eu, Mn (particle diameter: 6 μm) is used as a fluorescent substance, and is immersed in hexamethyldisilazane to impart hydrophobicity to the surface of the fluorescent substance and dried. The fluorescent substance which is subjected to the hydrophobic treatment is added to methyl methacrylate monomer, and further a small amount of V-65 is added thereto as a reaction initiator. A surfactant is further added to the methyl methacrylate monomer containing the fluorescent substance and reaction initiator added thereto, and the mixture is dispersed by an ultrasonic cleaner. Pure water is added to the resulting methyl methacrylate monomer solution, giving a reaction solution. The reaction solution in a container is placed in a temperature control furnace with rotating blades. The temperature in the furnace is maintained at 54° C. to allow reaction under a stream of nitrogen. The reaction solution is cooled, washed with water and then dried, preparing a wavelength conversion material used for the present invention.

Moreover, BaMgAI₁₀O₁₇:Eu, Mn having a particle diameter of 50 μm can be used as the fluorescent substance. Methyl methacrylate monomer is used as a raw material of the polymer. BaMgAl₁₀O₁₇:Eu, Mn (particle diameter: 50 μm) is used as the fluorescent substance, and immersed in hexamethyldisilazane to impart hydrophobicity to the surface of the fluorescent substance and dried. The fluorescent substance which is subjected to the hydrophobic treatment is added to methyl methacrylate monomer, and further a small amount of V-65 is added thereto as a reaction initiator. A surfactant is further added to the methyl methacrylate monomer containing the fluorescent substance and reaction initiator added thereto, and the mixture is dispersed by an ultrasonic cleaner. Pure water is added to the resulting methyl methacrylate monomer solution, giving a reaction solution. The reaction solution in a container is placed in a temperature control furnace with rotating blades. The temperature in the furnace is maintained at 54° C. under a stream of nitrogen to cause a reaction. The reaction solution is cooled, washed with water and then dried, preparing a wavelength conversion material used for the present invention.

Moreover, the wavelength conversion material can also be produced after the reaction initiator is applied on the surface of the fluorescent substance. Methyl methacrylate monomer is used as a raw material of the polymer. BaMgAl₁₀O₁₇:Eu, Mn (particle diameter: 6 μm) is used as the fluorescent substance, and immersed in hexamethyldisilazane to impart hydrophobicity to the surface of the fluorescent substance and dried. Moreover, a reaction initiator (V-65) is dissolved in a solution. The fluorescent substance is immersed in the dissolved reaction initiator solution and dried. A surfactant is further added to the methyl methacrylate monomer containing the treated fluorescent substance added thereto, and the mixture is dispersed by an ultrasonic cleaner. Pure water is added to the resulting methyl methacrylate monomer solution, giving a reaction solution. The reaction solution in a container is placed in a temperature control furnace with rotating blades, and the temperature in the furnace is maintained at 54° C. under a stream of nitrogen to cause a reaction. The reaction solution is cooled, washed with water and then dried, preparing a wavelength conversion material used for the present invention.

Next, a wavelength conversion material which is a fluorescent substance whose surface is coated with polymer is produced according to a second embodiment. In the wavelength conversion material according to the second embodiment, BaMgAl₁₀O₁₇:Eu, Mn (particle diameter: 1 μm) is used as a fluorescent substance, and immersed in hexamethyldisilazane to impart hydrophobicity to the surface of the fluorescent substance and dried. The rest of the processing is similar to that in the first embodiment.

Next, a wavelength conversion material which is a fluorescent substance whose surface is coated with polymer according to a third embodiment is produced. The wavelength conversion material according to the third embodiment (Ba, Ca, Sr) MgAl₁₀O₁₇:Eu, Mn (particle diameter: 6 μm) is used as a fluorescent substance, and immersed in hexamethyldisilazane to impart hydrophobicity to the surface of the fluorescent substance and dried. The rest of the processing is similar to that in the first embodiment.

Next, a wavelength conversion material which is a fluorescent substance whose surface is coated with polymer according to a fourth embodiment is produced. The fluorescent substance used is, as mentioned above, MgAl₁₀O₁₇:Eu, Mn, where M is a fluorescent substance which is one or more elements selected from Ba, Sr and Ca, or a fluorescent substance whose parent material contains one of (Ba, Sr)₂SiO₄, (Ba, Sr, Ca)₂SiO₄, Ba₂SiO₄, Sr₃SiO₅, (Sr, Ca, Ba)₃SiO₅, (Ba, Sr, Ca) ₃MgSi₂O₈, Ca₃Si₂O₇, Ca₂ZnSi₂O₇, Ba₃Sc₂Si₃O₁₂ and Ca₃Sc₂Si₃O₁₂, or a fluorescent substance whose parent material is represented by MAlSiN₃, where M is a fluorescent substance which is one or more elements selected from Ba, Sr, Ca and M. The fluorescent substance having a particle diameter of 1 to 50 μm can be used to produce a wavelength conversion material which is a polymer surface-coated fluorescent substance in a manner similar to the method stated above. The rest of the process is similar to that in the first embodiment. Moreover, in addition to acrylic resins, polyethylene, vinyl chloride resins and other materials can be used as the polymer for coating the fluorescent substance.

### <Production of Solar Cell Module>

Next, a solar cell module is produced using the wavelength conversion material. Described below is the solar cell module according to the first embodiment. Small amounts of organic peroxide, a crosslinking auxiliary agent and an adhesion improver are added to a clear resin (EVA). 1.0% by weight of a wavelength conversion material prepared by coating the surface of a fluorescent substance (Ba, Ca, Sr)MgAl₁₀O₁₇:Eu, Mn with an acrylic resin is mixed into the mixture. After the resulting mixture is kneaded using a roll mill heated to 80° C., it is nipped between two films of polyethylene terephthalate by using a press, and a sealing material 3 containing EVA as a main component and having a thickness of 500 μm is produced. Moreover, the fluorescent substance may be composed of a single component or a mixture of components. Next, this sealing material 3 is allowed to cool to room temperature, and the polyethylene terephthalate films are removed therefrom. The sealing material 3 is laminated with the front glass 2, solar battery cell 4 and back sheet 5 as shown in FIG. 1. The laminate is pre-crimped by a vacuum laminator set at 150° C. The pre-crimped laminate is heated in an oven at 155° C. for 30 minutes to cause crosslinking and adhesion, producing a solar cell panel 1. In the present invention, the fluorescent substance has the satisfactory excitation band as the wavelength conversion material, and the wavelength conversion material having high phototransformation efficiency is further used. Therefore, the amperage of the solar cell panel is high, and the amperage is increased by 10% than in the case where no wavelength conversion material is used.

The solar cell module according to the second embodiment is produced. In second embodiment, small amounts of organic peroxide, a crosslinking auxiliary agent and an adhesion improver are added to a clear resin (EVA). 2.0% by weight of a wavelength conversion material prepared by coating the surface of a fluorescent substance (Ba, Sr)₂SiO₄:Eu with an acrylic resin is mixed into the mixture. The resulting mixture is kneaded using a roll mill heated to 80° C. The rest of the processing is similar to that in the first embodiment. The amperage is increased by 7% by this embodiment compared with the case where no wavelength conversion material is used.

A solar cell module according to a third embodiment is produced. Small amounts of organic peroxide, a crosslinking auxiliary agent and an adhesion improver are added to a clear resin (EVA), and 2.0% by weight of a wavelength conversion material prepared by coating the surface of a fluorescent substance CaAlSiN₃:Eu with vinyl chloride is mixed into the mixture. The resulting mixture is kneaded using a roll mill heated to 80° C. The rest of the processing is similar to that in the first embodiment. The amperage increases by 5% by this embodiment compared with the case where no wavelength conversion material is used.

What is claimed is:

1. A seal sheet used for solar cells,
wherein a fluorescent substance is mixed into a sealing material which protects a solar cell, and
the fluorescent substance is, when an index of refraction of the sealing material is a and an index of refraction of the fluorescent substance is b, coated on its surface with polymer having an index of refraction c, and the index of refraction of the polymer coating material is a<c<b.

2. The seal sheet according to claim 1, wherein a material of the polymer coating is methyl methacrylate resin.

3. The seal sheet according to claim 1, wherein a material of the polymer coating is one of polyethylene and a vinyl chloride resin.

4. The seal sheet according to claim 1, wherein the composition of the fluorescent substance is MMgAl₁₀O₁₇:Eu, Mn, and M is one or more elements selected from Ba, Sr and Ca.

5. The seal sheet according to claim 1, wherein a parent material of the fluorescent substance contains one of (Ba, Sr)₂SiO₄, (Ba, Sr, Ca)₂SiO₄, Ba₂SiO₄, Sr₃SiO₅, (Sr, Ca, Ba)₃SiO₅, (Ba, Sr, Ca)₃MgSi₂O₈, Ca₃Si₂O₇, Ca₂ZnSi₂O₇, Ba₃Sc₂Si₃O₁₂ and Ca₃Sc₂Si₃O₁₂.

6. The seal sheet according to claim 1, wherein a parent material of the fluorescent substance is represented by MAlSiN₃, and M is one or more elements selected from Ba, Sr, Ca and Mg.

7. The seal sheet according to claim 1, wherein the thickness of the polymer coating is 70 nm or more.

8. The seal sheet according to claim 1, wherein the sealing material contains ethylene-vinyl acetate copolymer (EVA) as a main component.

9. The seal sheet according to claim 1, wherein the sealing material contains one or more additives selected from organic peroxide, a crosslinking auxiliary agent and an adhesion improver.

10. A solar cell module having a structure in which a material containing a fluorescent substance is placed on a path of light to a solar cell,
wherein the fluorescent substance is, when an index of refraction of the sealing material is a and an index of refraction of the fluorescent substance is b, coated on its surface with polymer having an index of refraction c, and the index of refraction of the polymer coating material is a<c<b.

11. The solar cell module according to claim 10, wherein the fluorescent substance is MMgAl₁₀O₁₇:Eu, Mn, and M is one or more elements selected from Ba, Sr and Ca.

12. The solar cell module according to claim 10, wherein a parent material of the fluorescent substance contains one of (Ba, Sr)₂SiO₄, (Ba, Sr, Ca)₂SiO₄, Ba₂SiO₄, Sr₃SiO₅, (Sr, Ca, Ba)₃SiO₅, (Ba, Sr, Ca)₃MgSi₂O₈, Ca₃Si₂O₇, Ca₂ZnSi₂O₇, Ba₃Sc₂Si₃O₁₂ and Ca₃Sc₂Si₃O₁₂.

13. The solar cell module according to claim 10, wherein a parent material of the fluorescent substance is represented by MAlSiN₃, and M is one or more elements selected from Ba, Sr, Ca and Mg.

14. The seal sheet according to claim 1, wherein an average particle diameter of the fluorescent substance is 1 μm or more and 50 μm or less.

15. The solar cell module according to claim 10, wherein an average particle diameter of the fluorescent substance is 1 μm or more and 50 μm or less.
